(19) United States
(12) Patent Application Publication
(10) Pub. No.: US 2016/0064589 A1
(43) Pub. Date: Mar. 3, 2016

(54) SOLAR CELL MODULE

(71) Applicants: SHENZHEN BYD AUTO R&D COMPANY LIMITED, Guangdong (CN); BYD COMPANY LIMITED, Guangdong (CN)

(72) Inventors: Zhanfeng Jiang, Shenzhen (CN); Jingbo Guan, Shenzhen (CN); Yunjiang Yao, Shenzhen (CN); Yu Wu, Shenzhen (CN); Bo Fang, Shenzhen (CN); Qiang Chen, Shenzhen (CN)

(73) Assignee: BYD Company Limited, Shenzhen (CN)

(21) Appl. No.: 14/785,786

(22) PCT Filed: Apr. 22, 2014
(86) PCT No.: PCT/CN2014/075910

§ 371 Date: Oct. 20, 2015

(30) Foreign Application Priority Data
Apr. 22, 2013 (CN) 201320204364.2

(51) Int. Cl. H01L 31/054; H01L 31/048

(52) U.S. Cl. CPC H01L 31/0547; H01L 31/048

(57) ABSTRACT

A solar cell module includes a transparent layer; a plurality of cells disposed on an upper surface of the transparent layer and spaced apart from each other; a reflective layer disposed on the upper surface of the transparent layer and surrounding at least a portion of a peripheral of at least one cell; and a cover plate disposed above, the plurality of cells and the reflective layer. At least a part, opposed to the reflective layer, of a lower surface of the cover plate has a serrate shape.

### CROSS-REFERENCE TO RELATED APPLICATION

This application claims priority to and benefits of Chinese Patent Application No. 201320204364.2, filed with the State Intellectual Property Office of P. R. China on Apr. 22, 2013, the entire content of which is incorporated herein by reference.

### FIELD

Embodiments of the present disclosure generally relate to field of solar battery, especially relate to a solar cell module.

### BACKGROUND

The conventional photovoltaic cell modules substantially include two types. One type of photovoltaic cell module contains a top layer made from photovoltaic glass, a back board made from TPT or other polymer materials, and an encapsulating layer made from EVA or PVB. This type of photovoltaic cell module has low encapsulating efficiency, low efficiency for converting light into electric energy, low utilization rate of light and has no decoration use. The other type of photovoltaic cell module contains a top layer and a back board both made from photovoltaic glass, a solar cell module arranged between the top layer and the back board, and an encapsulating layer made from EVA or PVB. However, due to the back board is transparent; this type of photovoltaic cell module has very poor reflectivity. The light reached the areas other than the photovoltaic areas of the photovoltaic cell module may pass through these areas directly, therefore the utilization rate of light may be reduced. And the efficiency for converting light into electric energy by the photovoltaic cell module needs to be improved.

### SUMMARY

Embodiments of the present disclosure seek to solve at least one of the problems existing in the prior art to at least some extent, or to provide a consumer with a useful alternative.

Embodiments of one aspect of the present disclosure provide a solar cell module. The solar cell module may include: a transparent layer; a plurality of cells disposed on an upper surface of the transparent layer and spaced apart from each other; a reflective layer disposed on the upper surface of the transparent layer and surrounding at least a portion of a peripheral of at least one cell; and a cover plate disposed above the plurality of cells and the reflective layer, in which at least a part, opposed to the reflective layer, of a lower surface of the cover plate has a serrate shape.

In some embodiments, the plurality of cells may be attached to the cover plate via a first adhesive layer, and the plurality of cells may be attached to the transparent layer via a second adhesive layer.

In some embodiments, each of the first and second adhesive layers may contain at least one of ethylene-vinyl acetate copolymer and polyvinyl butyral.

In some embodiments, an upper surface of the reflective layer may be spaced apart from the lower surface of the cover plate.

In some embodiments, the upper surface of the reflective layer may be a flat surface.

In some embodiments, the reflective layer may contain polymer material.

In some embodiments, the reflective layer may contain at least one selected from the group consisting of: fluorocarbon resin, polyvinylidene fluoride, polyethylene, fluorocarbon resin modified polymer, polyvinylidene fluoride modified polymer and polyethylene modified polymer.

In some embodiments, a tip angle of a tooth formed on the at least part of the lower surface of the cover plate may be about 45° to about 135°. In some embodiments, the tip angle may be about 60° to about 100°. In an embodiment, the tip angle may be about 60°.

In some embodiments, the cover plate may contain at least one selected from a group consisting of: photovoltaic glass, coated glass and textured glass.

In some embodiments, the transparent layer may contain glass.

In some embodiments, the reflective layer may surround the peripheral of each of the plurality of cells.

In some embodiments, the cell may be rectangular, and the reflective layer may be disposed adjacent to four sides of each of the plurality of cells.

In some embodiments, the reflective layer may be spaced apart from the cell.

According to embodiments of the present disclosure, the solar cell module includes the transparent layer and the reflective layer, therefore light illuminated from two opposite sides (for example, from the cover plate and the transparent layer) may both reach the cell and then be utilized by the cell. In some embodiments, the light illuminated into gaps between adjacent cells or edges of the cells from the cover plate (i.e. an area covered by the reflective layer) may be first reflected to the area having a serrate shape (also referred as a serration area, on the lower surface of the cover plate which is opposed to the reflective layer) by the reflective layer (via plane reflection in case the reflective layer has a flat surface), and then secondly reflected to cells. In this way, the utilization efficiency of light may be further improved, and the output power of the solar cell module may be improved accordingly. In addition, the reflective layer and the plurality of cells may form a riveting structure with each other, which may not only improve the mechanical stability of the solar cell module, but also increase the service life of the solar cell module.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the accompanying drawings, in which:

FIG. 1 is a cross-sectional view of a solar cell module according to an embodiment of the present disclosure;

FIG. 2 is a cross-sectional view of a solar cell module according to an embodiment of the present disclosure;

FIG. 3 is a schematic view of a solar cell module according to an embodiment of the present disclosure;

FIG. 4 is a cross-sectional view of a solar cell module according to an embodiment of the present disclosure;

FIG. 5 is a schematic view of a solar cell module according to an embodiment of the present disclosure; and

FIG. 6 is a cross-sectional view of a solar cell module according to an embodiment of the present disclosure.

### DETAILED DESCRIPTION

Reference will be made in detail to embodiments of the present disclosure. The same or similar elements and the elements having same or similar functions are denoted by like reference numerals throughout the descriptions. The embodiments described herein with reference to drawings are explanatory, illustrative, and used to generally understand the present disclosure. The embodiments shall not be construed to limit the present disclosure.

In the description, unless specified or limited otherwise, it is to be understood that phraseology and terminology used herein with reference to device or element orientation (for example, terms like “upper”, “lower”, and the like) should be construed to refer to the orientation as then described or as shown in the drawings under discussion for simplifying the description of the present disclosure, but do not alone indicate or imply that the device or element referred to must have a particular orientation. Moreover, it is not required that the present disclosure is constructed or operated in a particular orientation.

In addition, terms such as “first” and “second” are used herein for purposes of description and are not intended to indicate or imply relative importance or significance.

For the purpose of the present description and of the following claims, the definitions of the numerical ranges always include the extremes unless otherwise specified.

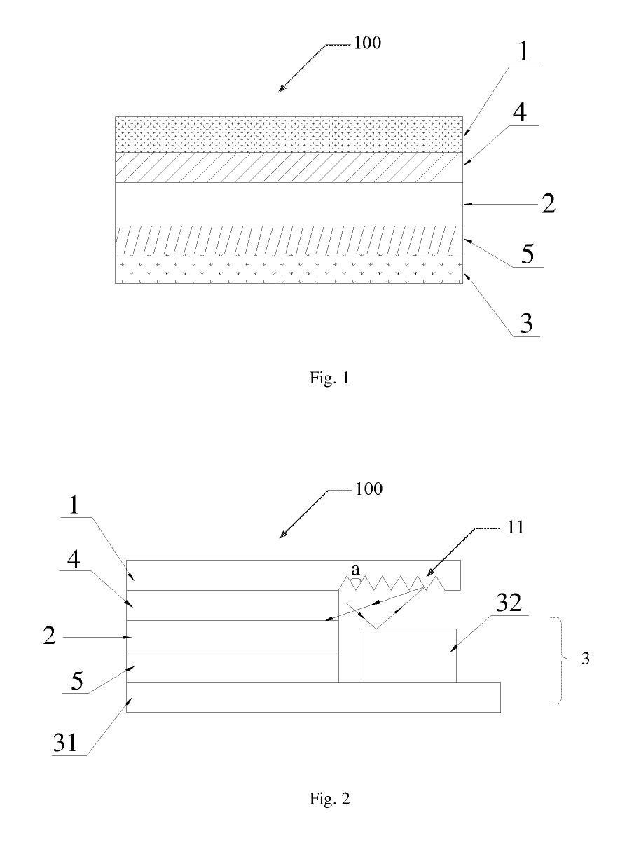

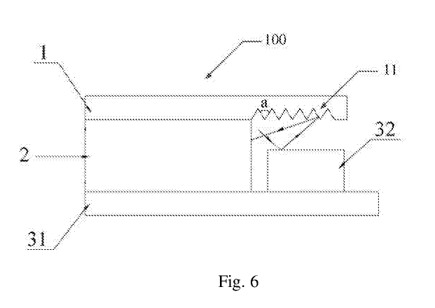

According to a first aspect of embodiments of the present disclosure, a solar cell module 100 is provided. With reference to FIGS. 1, 2, 4 and 6, the solar cell module 100 may include: a transparent layer 31, a plurality of cells 2, a reflective layer 32 and a cover plate 1.

In some embodiments, the plurality of cells 2 may be disposed on an upper surface of the transparent layer 31 and spaced apart from each other. In some embodiments, the reflective layer 32 may be disposed on the upper surface of the transparent layer 31 and surround at least a portion of a peripheral of at least one cell 2. In some embodiments, the cover plate 1 may be disposed above the plurality of cells 2 and the reflective layer 32. In some embodiments, at least a part 11, opposed to the reflective layer 32, of a lower surface of the cover plate 1 has a serrate shape.

In some embodiments, the transparent layer 31 and the reflective layer 32 may form a back plate of the solar cell module 100, as shown in FIGS. 1, 2, 4 and 6.

In some embodiments, the plurality of cells 2 may be attached to the cover plate 1 via a first adhesive layer 4, and the plurality of cells 2 may be attached to the transparent layer 31 via a second adhesive layer 5.

In some embodiments, each of the first and second adhesive layers 4, 5 may contain at least one of ethylene-vinyl acetate (EVA) copolymer and polyvinyl butyral (PVB). Then solar cell module 100 may have a good transmittance, cold resistance, heat resistance and long service life.

In some embodiments, the transparent layer 31 may contain glass.

In some embodiments, an upper surface of the reflective layer 32 may be spaced apart from the lower surface of the cover plate 1. Specifically, the upper surface of the reflective layer 32 and the reflective layer 32 may be out of touch with each other, as shown FIGS. 2, 4 and 6.

In some embodiments, the upper surface of the reflective layer 32 may be a flat surface. Then the reflective layer 32 may perform a plane reflection, which may reflect light to the cover plate 1.

In some embodiments, the reflective layer 32 may contain polymer material. In some embodiments, the reflective layer 32 may contain at least one selected from the group consisting of: fluorocarbon resin, polyvinylidene fluoride, polyethylene, fluorocarbon resin modified polymer, polyvinylidene fluoride modified polymer and polyethylene modified polymer. Then the solar cell module 100 may have high reflectivity and excellent aging resistance.

In some embodiments, the reflective layer 32 may surround the peripheral of each of the plurality of cells 2. Then the reflective layer 32 may form a netlike structure, as shown in FIG. 5.

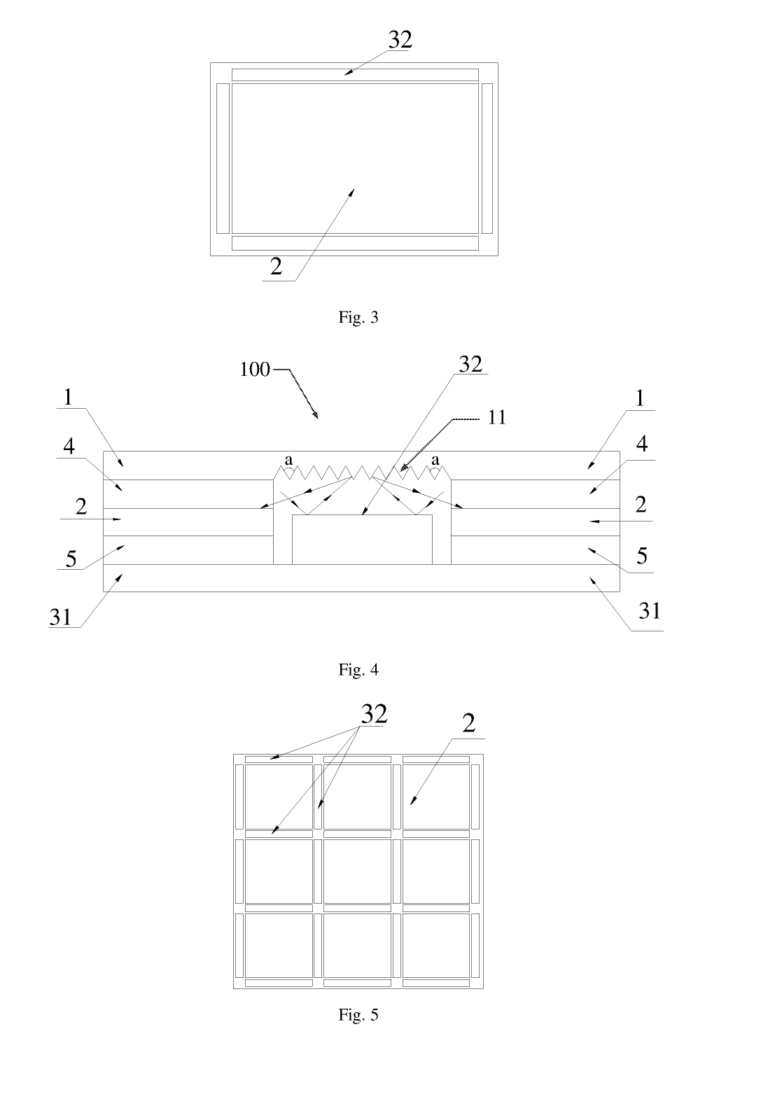

In some embodiments, the cell 2 may be rectangular, and the reflective layer 32 may be disposed adjacent to four sides of each of the plurality of cells 2, as shown in FIGS. 3 and 5.

In some embodiments, the reflective layer 32 may be spaced apart from the cell 2.

There are no particular limits to the method for preparing the reflective layer 32. In some embodiments, the method for forming the reflective layer 32 on the transparent layer 31 may include at least one of spraying, coating or printing.

In some embodiments, a tip angle α of a tooth formed on the at least part 11 of the lower surface of the cover plate may be about 45° to about 135°. In some embodiments, the tip angle α may be about 60° to about 100°. In an embodiment, the tip angle α may be about 60°.

In some embodiments, the cover plate 1 may contain at least one selected from a group consisting of: photovoltaic glass, coated glass and textured glass. The coated glass may include a coating which facilitates to reduce the reflection. The textured glass may improve the transmittance of the glass. Then the light absorbance of the solar cell module 100 may be improved and the light reflection may be reduced.

In some embodiments, the cell 2 may be a mono-crystalline cell or a polycrystalline cell.

According to embodiments of the present disclosure, the light illuminated from two opposite sides (for example, from the cover plate 1 and the transparent layer 31) may both reach and be utilized by the cell 2. Specifically, the light illuminated into gaps between adjacent cells 2 or the edges of the cell 2 from the cover plate 1 may be first reflected to the part 11 by the reflective layer 32, and then secondly reflected to cells 2. The detailed reflecting routes of the light are indicated by arrows in FIGS. 2, 4 and 6. With the two reflecting effects, the utilization rate of light may be improved, and the output power of the solar cell module 100 may be improved accordingly. In addition, the reflective layer 32 and the plurality of cells 100 may form a riveting structure with each other, which may not only improve the mechanical stability of the solar cell module 100, but also increase the service life of the solar cell module 100.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

1. A solar cell module comprising:
a transparent layer;
a plurality of cells disposed on an upper surface of the transparent layer and spaced apart from each other;
a reflective layer disposed on the upper surface of the transparent layer and surrounding at least a portion of a peripheral of at least one cell; and
a cover plate disposed above the plurality of cells and the reflective layer, wherein at least a part, opposed to the reflective layer, of a lower surface of the cover plate has a serrate shape.

2. The solar cell module of claim 1, wherein the plurality of cells are attached to the cover plate via a first adhesive layer, and the plurality of cells are attached to the transparent layer via a second adhesive layer.

3. The solar cell module of claim 2, wherein each of the first and second adhesive layers comprises at least one of ethylene-vinyl acetate copolymer and polyvinyl butyral.

4. The solar cell module of claim 1, wherein the reflective layer comprises an upper surface, and the upper surface of the reflective layer is spaced apart from the lower surface of the cover plate.

5. The solar cell module of any of claim 4, wherein the upper surface of the reflective layer is a flat surface.

6. The solar cell module of claim 1, wherein the reflective layer comprises polymer material.

7. The solar cell module of claim 6, wherein the reflective layer comprises at least one selected from a group consisting of: fluorocarbon resin, polyvinylidene fluoride, polyethylene, fluorocarbon resin modified polymer, polyvinylidene fluoride modified polymer and polyethylene modified polymer.

8. The solar cell module of claim 1, wherein a tip angle of a tooth formed on the at least part of the lower surface of the cover plate is about 45° to about 135°.

9. The solar cell module of claim 8, wherein the tip angle is in about 60° to about 100°.

10. The solar cell module of claim 9, wherein the tip angle is about 60°.

11. The solar cell module of claim 1, wherein the cover plate comprises at least one selected from a group consisting of: photovoltaic glass, coated glass and textured glass.

12. The solar cell module of claim 1, wherein the transparent layer comprises glass.

13. The solar cell module of claim 1, wherein the reflective layer surrounds the peripheral of each of the plurality of cells.

14. The solar cell module of claim 1, wherein each of the plurality of cells is rectangular, and the reflective layer is disposed adjacent to four sides of each of the plurality of cells.

15. The solar cell module of claim 1, wherein the reflective layer is spaced apart from at least one of the plurality of the cells.
